(19) United States
(12) Patent Application Publication
(10) Pub. No.: US 2015/0380214 A1
(43) Pub. Date: Dec. 31, 2015

(54) LITHOGRAPHY APPARATUS, AND METHOD OF MANUFACTURING ARTICLE

(71) Applicant: CANON KABUSHIKI KAISHA, Tokyo (JP)

(72) Inventors: Shigeki Ogawa, Utsunomiya-shi (JP); Hiromi Kinebuchi, Yokohama-shi (JP)

(21) Appl. No.: 14/753,639

(22) Filed: Jun. 29, 2015

(30) Foreign Application Priority Data
Jun. 30, 2014 (JP) 2014-134545

(51) Int. Cl. H01J 37/317; H01J 37/04

(52) U.S. Cl. CPC H01J 37/3177; H01J 37/045

(57) ABSTRACT

Provided is a lithography apparatus that performs patterning on a substrate with a plurality of beams, the apparatus comprising: an optical system configured to irradiate the substrate with the plurality of beams; and a controller configured to control the optical system, wherein the controller is configured to control the optical system so as to form a first pattern for an article in a first region of the substrate and form a second pattern for an inspection of the plurality of beams in a second region, different from the first region, of the substrate.

### BACKGROUND OF THE INVENTION

1. Field of the Invention

The present invention relates to a lithography apparatus that performs patterning on a substrate with a plurality of beams and a method of manufacturing an article.

2. Description of the Related Art

A lithography apparatus that performs patterning on a substrate with a plurality of beams (charged particle beams or the like) is known. Such a lithography apparatus can cause a defect in the patterning when a defect of the beam (a defect relating to a characteristic of the beam or blanking) occurs. Japanese Patent Application Publication No. 10-64799 discloses a drawing apparatus that includes reflected electron detectors provided at each electron optical system and that adjusts each electron beam. Additionally, Japanese Patent Application Publication No. 2008-41890 discloses an exposure apparatus (drawing apparatus) that obtains information about the characteristics of the plurality of charged particle beams by using a fluorescent material that emits light by irradiation of the plurality of charged particle beams.

There are various reasons for the occurrence of the defect as described above, and the timing is difficult to predict. Therefore, it is preferable to perform an inspection of the defect with as high a frequency as possible, and so as not to decrease the productivity (throughput) due to the inspection.

### SUMMARY OF THE INVENTION

The present invention provides, for example, a lithography apparatus advantageous in compatibility of frequency in inspection of a beam thereof and productivity thereof.

The present invention is a lithography apparatus that performs patterning on a substrate with a plurality of beams, the apparatus comprising: an optical system configured to irradiate the substrate with the plurality of beams; and a controller configured to control the optical system, wherein the controller is configured to control the optical system so as to form a first pattern for an article in a first region of the substrate and form a second pattern for an inspection of the plurality of beams in a second region, different from the first region, of the substrate.

Further features of the present invention will become apparent from the following description of exemplary embodiments (with reference to the attached drawings).

### BRIEF DESCRIPTION OF THE DRAWINGS

FIG. 1 is a schematic diagram illustrating a configuration of a drawing apparatus according to one embodiment of the present invention.

FIG. 2 illustrates a drawn pattern when beams are normal or a defect is present in the beams.

FIG. 3 is a diagram that extracts a drawn pattern when a defect is present in the beams in FIG. 2.

FIG. 4 illustrates one example of an inspection pattern according to one embodiment of the present invention.

FIG. 5 illustrates another example of the inspection pattern according to one embodiment of the present invention.

FIG. 6 is a diagram in which the inspection pattern according to one embodiment is drawn on one substrate.

FIG. 7 is a diagram in which the inspection pattern according to one embodiment is drawn on one substrate.

FIG. 8 is a flowchart of a process of a controller according to one embodiment.

### DESCRIPTION OF THE EMBODIMENTS

Hereinafter, a detailed description will be given of embodiments for performing the present invention with reference to attached drawings.

### First Embodiment

Firstly, a description will be given of a lithography apparatus according to one embodiment of the present invention. Hereinafter, the lithography apparatus according to the present embodiment is a multi-beam type charged particle beam drawing apparatus (drawing apparatus) as described below, as one example. The multi-beam type charged particle beam drawing apparatus (drawing apparatus) draws predetermined data to be drawn at a predetermined position on a substrate to be treated by deflecting a plurality of electron beams (charged particle beams) and separately controlling ON/OFF of the irradiation of the electron beams. Here, the charged particle beam is not limited to the electron beam as described in the present embodiment, and it may be another charged particle beam including an ion beam. Additionally, for example, the drawing apparatus may be a light beam drawing apparatus that performs drawing by appropriately diffracting and controlling a light beam (laser beam) by using an acoustic optical element.

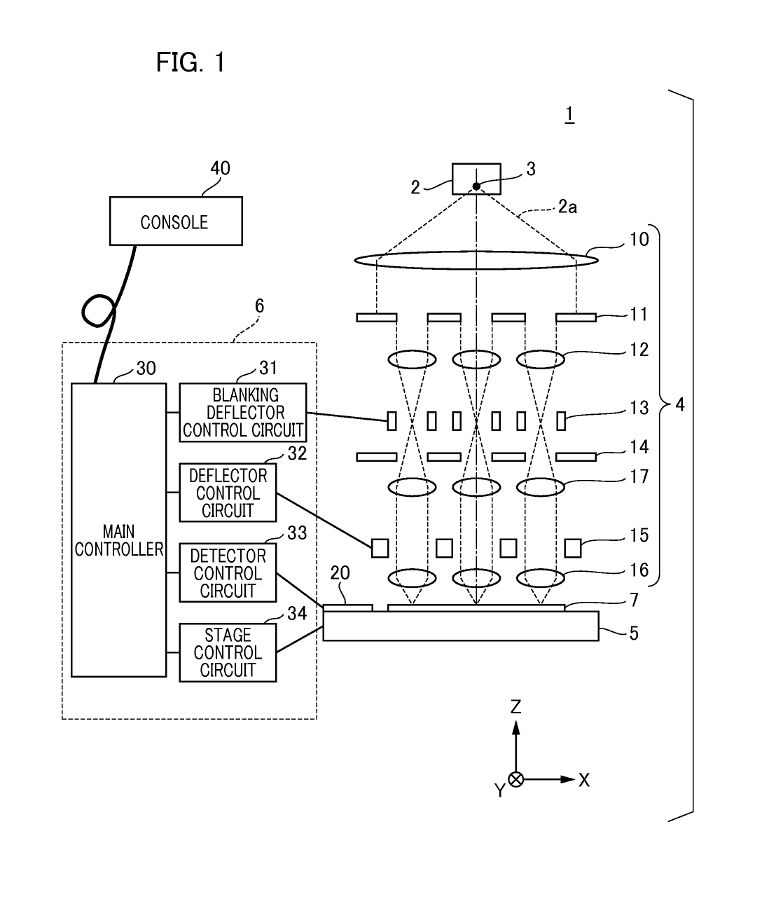

FIG. 1 is a schematic diagram illustrating a configuration of the drawing apparatus according to the present embodiment. Note that, in each of the drawings, the Z-axis is positioned in an irradiation direction of the electron beam with respect to the substrate to be treated, and the X-axis and the Y-axis that are orthogonal each other are positioned in a plane vertical to the Z-axis. Moreover, in each of the drawings below, the same reference numerals are provided to each of the components that are same as those in FIG. 1. A drawing apparatus 1 includes an electron gun 2, an optical system 4 that divides an electron beam dispersed from a crossover 3 of the electron gun 2 into a plurality of electron beams, deflects them and forms images, a substrate stage 5 that holds the substrate to be treated, and a controller 6 that controls the operation of each component of the drawing apparatus 1. Note that the above components excluding the controller 6 and a console 40 are disposed in a space where internal pressure is appropriately adjusted by a vacuum pumping system (not illustrated) because the electron beam is soon attenuated in an atmospheric-pressure environment (atmospheric-pressure ambience) and for the purpose of preventing an electric discharge due to a high voltage. For example, the electron gun 2 and the optical system 4 are disposed in an electron optical barrel maintained at a high degree of vacuum. Similarly, the substrate stage 5 is disposed in a chamber maintained at a degree of vacuum relatively lower than the inside of the electron optical barrel. Additionally, a substrate to be treated 7 is, for example, a substrate consisting of single crystal silicon and a photosensitive resist is applied on the surface thereof.

The electron gun 2 is a mechanism that discharges the electron beam by heat or the application of an electric field, and in FIG. 1, traces 2a of the electron beam discharged from the crossover 3 are shown with a dotted line. The optical system 4 includes, in order from the electron gun 2, a collimator lens 10, an aperture array 11, a first electrostatic lens array 12, a blanking deflector array 13, a blanking aperture array 14, a deflector array 15, and a second electrostatic lens array 16. Note that there may be a case in which the optical system 4 includes a third electrostatic lens array 17 at a downstream of the blanking aperture array 14. The collimator lens 10 is configured by an electromagnetic lens, and is an optical element that makes the electron beam dispersed at the crossover 3 parallel. The aperture array 11 has a plurality of circular openings arranged in a matrix, and is a mechanism that divides the electron beam incident from the collimator lens 10 into a plurality of electron beams. The first electrostatic lens array 12 is configured of three electrode plates having circular openings (three electrode plates are integrally illustrated in FIG. 1), and is an optical element that forms an image of the electron beam with respect to the blanking aperture array 14. The blanking deflector array 13 and the blanking aperture array 14 are both placed in a matrix, and they are mechanisms that perform ON (non-blanking state)/OFF (blanking state) operations of the irradiation of each electron beam. The deflector array (deflector) 15 is a mechanism that deflects an image on a surface of the substrate to be treated 7 mounted on the substrate stage 5 in the X-axis direction. The second electrostatic lens array 16 is an optical element that forms an image of the electron beams passing through the blanking aperture array 14 onto the substrate to be treated 7. Alternately, the second electrostatic lens array 16 is an optical element that forms the original image at the crossover 3 with respect to a measuring device (electron beam measuring device, electron beam detector) 20 disposed on the substrate stage 5 described below.

Note that, in the present embodiment, although the blanking is performed by shielding the electron beams by using the blanking deflector array 13 and the blanking aperture array 14, the present invention is not limited thereby. For example, the switchover to the non-reflection corresponds to the blanking in a device that switches between reflection and non-reflection of the electron (beam) by switching the voltage applied to a pixel.

The substrate stage 5 is a substrate holding unit having a configuration allowing six-axis control driving and it is appropriately movable in at least two axial directions (X and Y directions) while holding the substrate to be treated 7, for example, by electrostatic attraction, and the position of the substrate stage 5 is measured in real time by an interferometer (laser measuring unit, not illustrated) and the like. For example, the resolution at this time is about 0.1 nm. Additionally, the substrate stage 5 is provided with a measuring device 20 that measures the electron beam on the irradiated surface thereof. An output signal (electric signal) of the measuring device 20 is used for measuring an intensity distribution of the electron beam with respect to the change of the electron beam. Here, the intensity distribution indicates a shape, a position, and intensity of the electron beam. For example, a measuring method using a measuring slit can be employed for these measurements.

As shown in FIG. 1, the controller 6 has various control circuits that control the operation of each component relating to the drawing of the drawing apparatus 1 and a main controller 30 that controls the whole control circuits. The controller 6 includes a lens control circuit (not illustrated), a blanking deflector control circuit 31, a deflector control circuit 32, a detector control circuit 33, and a stage control circuit 34, as each of the control circuits. Firstly, the lens control circuit controls the operation of the collimator lens 10 and each of the electrostatic lens arrays 12, 16, and 17. The blanking deflector control circuit 31 controls the operation of the blanking deflector array 13 based on a blanking signal generated by using a drawing pattern generating circuit, a bit map converting circuit, and a blanking command generating circuit included in the controller 6. Here, the drawing pattern generating circuit generates a drawing pattern and this drawing pattern is converted into bit map data by the bit map converting circuit. The blanking command generating circuit generates a blanking signal based on the bit map data. The deflector control circuit 32 controls the operation of the deflector arrays 15 based on a deflection signal generated by the deflection signal generating circuit included in the controller 6.

The detector control circuit 33 determines the presence/absence of the irradiation of the electron beam after receiving an output from the measuring device 20, and transmits the determination result to the main controller 30. Additionally, the detector control circuit 33 measures the characteristic of the irradiated electron beam by cooperating also with the stage control circuit 34 described below through the main controller 30. Measurement items at this time are, for example, the shape, the position, and intensity of the electron beam. In this characteristic measurement, the detector control circuit 33 transmits the result detected at the measuring device 20 to the main controller 30. Additionally, the stage control circuit 34 also transmits position information of the stage at the time to the main controller 30 and the deflector control circuit 32 also transmits a deflection amount (deflection width) at the time to the main controller 30. Subsequently, the main controller 30 calculates the shape, the position, and the intensity of the electron beam based on each of data. However, a few beams selected from many beams are used for measuring the characteristic here, which serves to represent the characteristics of all of the beams. The reason is that each of tens of thousands to hundreds of thousands beams needs to be measured if the characteristic measurement is performed on all of the beams. Although the measurement of each of the beams is not impossible, it influences on the number of sheets per unit time for performing the drawing processing of the pattern on the substrate 7 when taking into consideration the measuring time required for that.

The stage control circuit 34 calculates a command target value for the substrate stage 5 based on stage position information (position coordinates) that is a command from the main controller 30 and drives the substrate stage 5 such that the position after driving becomes this target value. At this time, data measured by the interferometer is processed at the main controller 30 through the stage control circuit 34 and returned to the stage control circuit 34 again to be used for controlling the position of the substrate stage 5. Here, the stage control circuit 34 continuously scans the substrate to be treated 7 (substrate stage 5) in the Y-axis direction while drawing the pattern. At this time, the deflector array 15 deflects an image on the surface of the substrate to be treated 7 in the X-axis direction on the basis of the measuring result of the substrate stage 5 by the interferometer. Subsequently, the blanking deflector array 13 terns the irradiation of the electron beam ON and OFF so as to enable obtaining a target dose on the substrate to be treated 7.

Here, there are an alignment measuring device (not illustrated) that measures an alignment mark that is simultaneously formed when the pattern placed on the substrate is formed, and a calculating circuit (not illustrated) that calculates an drawing position based on the measured value. The drawing region and the non-drawing region of the device pattern are correctly found on the substrate by using the alignment information, and thus, the correct drawing of the beam inspection pattern is enabled.

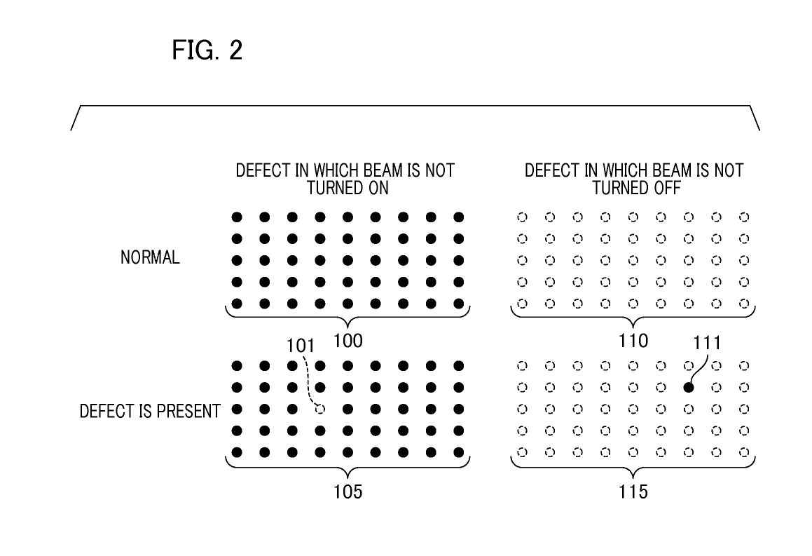

FIG. 2 illustrates patterns that are separately drawn when the beams are normal and when a defect is present in the beams. A pattern drawn on the substrate when the blanking command is turned ON is shown by black dots and a pattern drawn on the substrate when the blanking command is turned OFF is shown by white dots with broken lines. In a case where the beams are normal with respect to the blanking command, the pattern shown by all of black dots 100 when all of the blanking commands are turned ON or the pattern shown by all of white dots with broken lines 110 when all of the blanking commands are turned OFF is drawn on the substrate. If a defect is present in the beams with respect to the blanking command ON/OFF, a defect 101 indicating that the beam is not turned ON when the blanking command is turned ON is mixed and drawn like a pattern drawing 105 in which the blanking command is turned ON when the defect is present in the beams in FIG. 2. Similarly, a defect 111 indicating that the beam is not turned OFF when the blanking command is turned OFF is mixed and drawn like a pattern drawing 115 in which the blanking command is turned OFF when the defect is present in the beams in FIG. 2.

Note that although the expression “a pattern is drawn” is used when the blanking command is ON and when the blanking command is OFF for ease of explaining, in fact, “any pattern is not drawn” in an actual device either when the blanking command is ON or when the blanking command is OFF. Additionally, the inspection items of the beam are not limited to the above described blanking characteristics and there may be a case where the inspection of the intensity distribution is performed. Here, it is desirable that the beam inspection pattern to be drawn is performed in a same way of drawing as when an actual element pattern (actual device pattern) is drawn. That is, it is preferable that the beam inspection pattern is provided by a pattern corresponding to the beams one by one if the drawing of the actual element pattern is performed by joining each of the beams. Additionally, it is preferable that the beam inspection pattern is also provided by overlying a plurality of beams if the drawing of the actual element pattern is performed by overlying the plurality of beams.

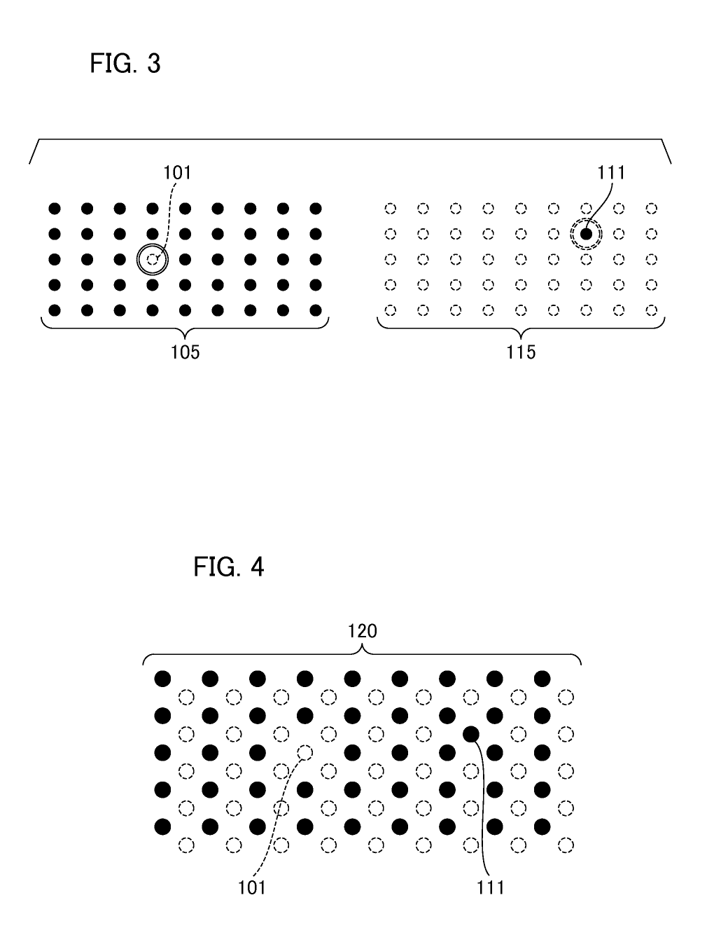

FIG. 3 is a diagram that extracts one example of the pattern that is drawn in the case where a defect is present in the beams when the beams are ON or the beams are OFF in FIG. 2. For example, the beam patterns when the beams are ON and when the beams are OFF as shown in FIG. 3 are drawn in a free region where the device pattern (first pattern) on the substrate is not drawn, and thus this drawing pattern is measured/inspected after the substrate processing and the presence/absence of the defect of the beam can be determined.

FIG. 4 illustrates one example of the beam inspection pattern (second pattern) according to the present embodiment. Abeam inspection pattern 120 illustrated in FIG. 4 is a pattern in which the drawing pattern of the beam ON/OFF is drawn by shifting only a half of the beam interval in each of the X direction and the Y direction with respect to the drawing position of the beam ON. Drawing in this way allows reducing a free region on the substrate needed for drawing the beam inspection pattern, and additionally it facilitates associating the defect that is found when the beam inspection is performed with the beam. In particular, a drawing method like this is important because it is not easy for the drawing apparatus having tens of thousands to hundreds of thousands beams to associate the result for the defect inspection with the defect of the actual beam for a defect in which the beam is emitted during the blanking command in which the beam is not drawn.

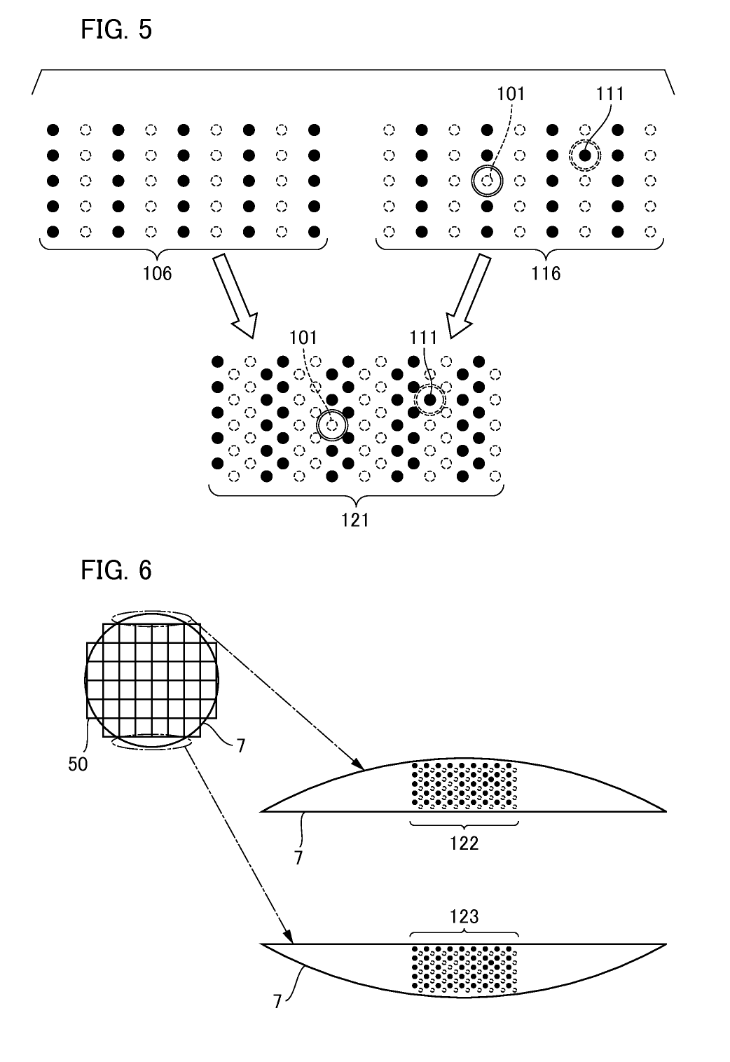

In the above drawings, the examples of the drawing of the beam inspection pattern when all of the beams are turned ON and when all of the beams are turned OFF are described, but the present invention is not limited thereby. For example, as shown in FIG. 5, it may be possible that the pattern is drawn in the order of beam ON and the beam OFF by each line and then the pattern is drawn in the order of the beam OFF and the beam ON by each line at a position shifting in a half pitch in the X and Y directions (beam inspection pattern 121). That is, the defect inspection of the beam is possible if two drawings, that is, the case in which the blanking command is ON and the case in which the blanking command is OFF, are performed for every beam inspection pattern of one beam, and thus there is no limitation to the combinations of ON and OFF.

As described above, because predicting the occurrence of a beam defect is impossible, it is assumed that, for example, a beam defect occurs during the drawing of one substrate. Here, when the beam inspection is performed before and after the device pattern drawing by each substrate in a conventional structure, a decrease in productivity is unavoidable, because the time for the beam inspection that is twice that of the number of substrate treatments is needed even if time for the beam inspection can be shortened. In contrast, according to the present embodiment, the beam inspection pattern is drawn at the start and the end of drawing the device pattern on one substrate in order to guarantee the presence/absence of the beam defect while drawing the device pattern. Subsequently, while executing the beam inspection based on the beam inspection pattern at another device that is one other than the drawing apparatus, drawing on another substrate is performed in parallel. Hence, it is possible to advance a treatment for another substrate without waiting for the result of the beam inspection, and it is possible to suppress the decrease in productivity. Here, at first, a description will be given of a configuration of the device pattern and the beam inspection pattern drawn on one substrate. FIG. 6 illustrates one example in which the inspection pattern is drawn before and after the drawing of the device pattern on one substrate. Because a rectangular device pattern is disposed with respect to a circular substrate, a free region where the device pattern cannot be drawn is present at the top, bottom, right or left of the substrate (peripheral region of outside the array of the shot regions). The drawing of the beam inspection pattern is performed in this region. FIG. 6 illustrates an example in which beam inspection patterns 122 and 123 of the blanking command ON/OFF are drawn in free regions in the upper and lower portions of the substrate. In this example, the beam inspection pattern 122 is, for example, a pattern that is drawn at the start of drawing the device pattern and 123 is a pattern that is drawn at the end thereof. There is no problem, of course, if this is reversed. Additionally, free regions are formed also on the right and left of the substrate, and thus, they may be used.

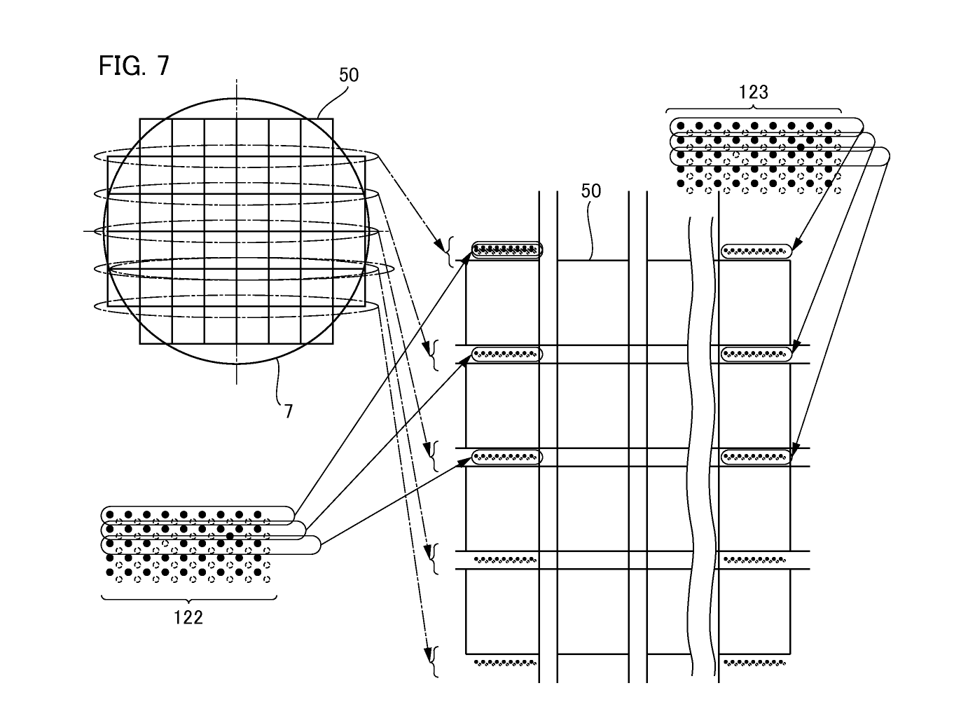

Additionally, there may be a case in which an region allowing all of the beam inspection drawings at once cannot be secured on the substrate. In this case, for example, as shown in FIG. 7, the beam inspection pattern is drawn in a space referred to as scribe lines between shots 50. It is difficult to secure a space for drawing all of the beams on one scribe line. Here, as shown in FIG. 7, for example, the beam inspection pattern is divided into several groups in accordance with the scribe lines, and the beam inspection patterns 122 and 123 of the blanking command ON/OFF are drawn on the scribe lines per group. In a manner similar to the case of FIG. 6, also in this example, the group of the beam inspection pattern 122 is a pattern drawn at the start of drawing the device pattern, and the group of the beam inspection pattern 123 is a pattern drawn at the end of drawing the device pattern. In the example of FIG. 7, the example of drawing to the scribe lines in a horizontal direction is illustrated, but the present invention is not limited thereby, and, for example, it is possible to draw the beam inspection pattern on the scribe line in a longitudinal direction. In that case, a grouping of the beam inspection pattern is performed in the longitudinal direction so as to align the scribe line in the longitudinal direction.

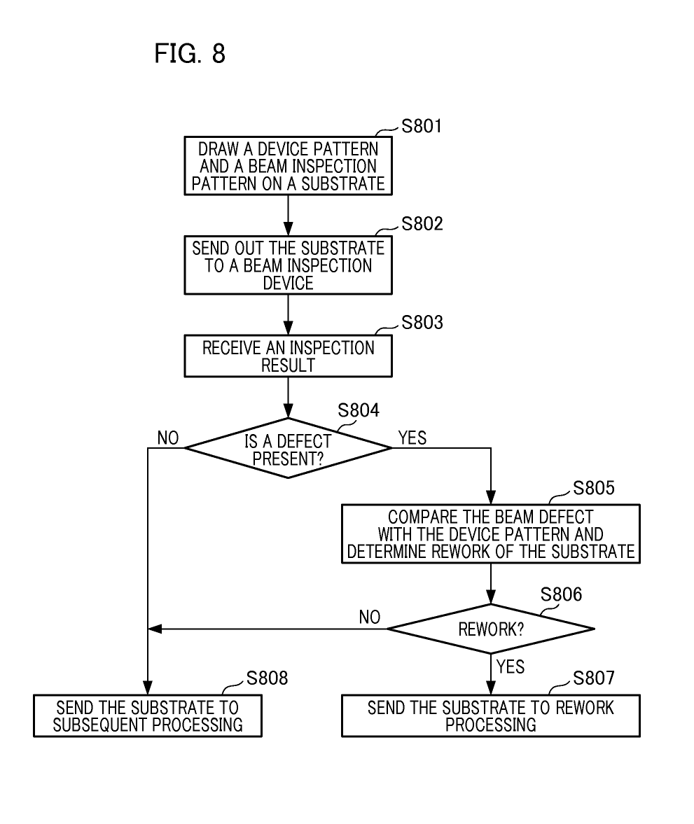

Next, a description will be given of a process flow of the controller 6 for the substrate by using a flowchart in FIG. 8, including a process after drawing the device pattern and the beam inspection pattern on the substrate as described above. First, in 801, the controller 6 performs the drawing of the device pattern on the substrate, and before and after that, performs the drawing of the beam inspection pattern on the substrate, as described above. Next, in 802, the substrate is sent to an inspection device for performing the beam inspection of the substrate on which the drawing is ended. At this time, the substrate may be developed or may not be developed. Additionally, the inspection device for performing the beam inspection is a device other than the drawing apparatus that has performed the pattern drawing on the substrate. Therefore, it is possible to perform defect processing of the beam in parallel with the drawing processing to the substrate. The controller 6 receives a result inspected by the inspection device in 803 and determines whether or not the defect is present in 804. As a result for the determination, when the defect is not present, the process proceeds to 808 and a subsequent process is performed on the substrate. When the defect is present, it may cause an influence on the fidelity of the drawing pattern. Specifically, there are cases in which the pattern to be drawn is not drawn as pattern data or it is drawn in an unrequired region. Accordingly, the substrate drawn in a state having the influence of the beam defect is turned to rework processing. For example, the drawing processing is performed again. Accordingly, the productivity decreases when the rework processing frequently occurs. Here, in 805, it is determined whether or not the rework of the substrate is needed based on the result for the drawn device pattern and the beam inspection. For example, it is possible to determine that the rework of the substrate is not needed when the beam is not used for drawing on the substrate even if there is a defect in which the beam is not turned ON. The controller 6 determines that the process proceeds to 808 and a subsequent process may be performed on the substrate when it is determined that the rework of the substrate is not needed by the determination in 805. The controller 6 determines that the process proceeds to 807 and reworking processing of the substrate should be performed when it is determined that the rework of the substrate is needed according to the determination in 805. According to the present embodiment, the beam inspection is performed in parallel with the drawing processing on another substrate that is not the inspected substrate, and therefore the rework processing may be performed from the inspected substrate up to a substrate on which the drawing processing has been performed by the end timing of the rework determination in 806. Additionally, when it is determined that the defect is present in 804, the controller 6 commands a control target including a column and a stage to compensate or reduce the influence of the defect from the result for the beam. inspection. Here, the controller 6 can change at least either of, for example, the drawing data or drawing sequence (procedure) so as to compensate or reduce the influence of the defect. Note that if the beam inspection and the handling (compensation) in the lithography apparatus in a case where the defect is present as the result for the beam inspection can be performed within the time for drawing of one substrate, only two substrates are needed for the rework processing.

As described above, according to the present embodiment, it is possible to provide the lithography apparatus that allows suppressing the decrease in the productivity due to a time required for the beam inspection without increasing the apparatus cost and that allows the inspection with high frequency. Additionally, only the minimum necessary rework processing is required even when the beam defect occurs, and thus the substrate can be treated with optimum productivity and apparatus cost that are requested by a user.

### Article Manufacturing Method

An article manufacturing method according to an embodiment of the present invention is preferred in manufacturing an article such as a micro device such as a semiconductor device or the like, an element or the like having a microstructure, or the like. The article manufacturing method may include a step of forming a pattern (e.g., latent image pattern) on an object (e.g., substrate on which a photosensitive material is coated) using the aforementioned lithography apparatus; and a step of processing (e.g., step of developing) the object on which the latent image pattern has been formed in the previous step. Furthermore, the article manufacturing method may include other known steps (oxidizing, film forming, vapor depositing, doping, flattening, etching, resist peeling, dicing, bonding, packaging, and the like) . The device manufacturing method of this embodiment has an advantage, as compared with a conventional device manufacturing method, in at least one of performance, quality, productivity, and production cost of a device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-134545 filed Jun. 30, 2014, which is hereby incorporated by reference herein in its entirety.

What is claimed is:

1. A lithography apparatus that performs patterning on a substrate with a plurality of beams, the apparatus comprising:
an optical system configured to irradiate the substrate with the plurality of beams; and
a controller configured to control the optical system,
wherein the controller is configured to control the optical system so as to form a first pattern for an article in a first region of the substrate and form a second pattern for an inspection of the plurality of beams in a second region, different from the first region, of the substrate.

2. The apparatus according to claim 1, wherein the second pattern includes a pattern for an inspection with respect to an intensity of a beam of the plurality of beams.

3. The apparatus according to claim 1, wherein the second pattern includes a pattern for an inspection with respect to a blanking characteristic of a beam of the plurality of beams.

4. The apparatus according to claim 1, wherein the second region includes a region corresponding to a scribe line of the substrate.

5. The apparatus according to claim 1, wherein the second region includes a peripheral region on the substrate outside an array of shot regions on the substrate.

6. The apparatus according to claim 1, wherein the controller is configured to control the optical system so as to form the second pattern before and after formation of the first pattern.

7. A method of manufacturing an article, the method comprising steps of:
performing patterning on a substrate using a lithography apparatus that performs patterning with a plurality of beams;
developing the substrate on which the patterning has been performed; and
processing the developed substrate to manufacture the article,
wherein the apparatus comprises:
an optical system configured to irradiate the substrate with the plurality of beams; and
a controller configured to control the optical system,
wherein the controller is configured to control the optical system so as to form a first pattern for an article in a first region of the substrate and form a second pattern for an inspection of the plurality of beams in a second region, different from the first region, of the substrate.

8. A method of manufacturing an article, the method comprising steps of:
performing patterning on a substrate with a plurality of beams;
inspecting the substrate on which the patterning has been performed;
wherein the patterning forms a first pattern for the article in a first region of the substrate and a second pattern for inspection of the plurality of beams in a second region, different from the first region, of the substrate,
wherein the inspecting performs inspection of the plurality of beams based on the second pattern formed on the substrate, and
wherein in a case where the inspecting performs the inspection of the plurality of beams, the patterning forms a pattern based on the performed inspection.
